(19) United States
(12) Patent Application Publication
(10) Pub. No.: US 2005/0072669 A1
(43) Pub. Date: Apr. 7, 2005

(54) Deposition apparatus, deposition method, optical element, and optical system

(76) Inventors: Koji Teranishi, Tochigi (JP); Yasuyuki Suzuki, Kanagawa (JP)

Correspondence Address: MORGAN & FINNEGAN, L.L.P., 3 WORLD FINANCIAL CENTER, NEW YORK, NY, 10281-2101, US

(21) Appl. No.: 10/953,931

(22) Filed: Sep. 29, 2004

(30) Foreign Application Priority Data
Oct. 2, 2003 (JP) 2003-344387

(51) Int. Cl. G02B 25/00; C23C 14/34

(52) U.S. Cl. 204/298.18; 204/298.06; 204/298.07; 204/298.08; 204/298.12; 204/298.13; 359/642

(57) ABSTRACT

A deposition apparatus generates plasma by applying voltage to a target, deposits target's particles that are vaporized by the plasma onto a surface of an object, and forms a thin film onto the surface of the object, and also includes a plasma direction unit that directs the plasma generated by the application of the voltage.

### BACKGROUND OF THE INVENTION

The present invention generally relates to a deposition apparatus that forms a thin film onto a surface of a substrate such as an optical element, particularly to a deposition apparatus that forms a thin film such as a reflection coating film or an anti-reflection coating film onto a surface of a substrate such as a lens or a mirror used in a semiconductor exposure apparatus. Here, “the deposition” means the same as “the film forming”.

A reflection coating film, anti-reflection coating film, or the like (hereinafter, “a thin film”) formed on a substrate's surface of an optical element or the like generally uses each one of low refraction material such as magnesium fluoride (MgF₂) or high refraction material such as aluminum oxide (Al₂O₃), or both of them. The thin film is formed (deposited) by being controlled on its thickness according to the optical performance demanded, or by being controlled on its layer structure when the thin film is a multi layer film.

A vacuum evaporation method is generally used for forming the thin film because it can form the thin film with high speed despite of large area of the substrate as an object to be deposited. However, an apparatus used for the vacuum evaporation method has problems of its large size, difficulty of fine control of the film thickness, and difficulty for applying to the auto-manufacturing. The vacuum evaporation method also has a problem that the thin film becomes weak in its mechanical strength when the depositing should be done in low temperature. Thus, depositing by using a spattering method has recently attracted because it is thought to have good performances in view of the improvement of the manufacturing efficiency by saving processes, quality stability of the thin film, and performance of the thin film (strength, adhesiveness).

Meanwhile, a semiconductor exposure apparatus (hereinafter, “an exposure apparatus”) that is called “a stepper” or “a scanner” is used for exposing and transforming a fine pattern of a semiconductor integrated circuit. Wavelength of an exposure light source of the exposure apparatus have become shorter from an ArF laser (wavelength of 193 nm) to a F2 excimer laser (wavelength of 157 nm). As the exposure apparatus has many lenses, the loss by transmittance after the exposure light passes through many lenses will become large in spite that the loss by transmittance of one lens is small. In this case, the light intensity at an illumination surface of an object to be exposed will not be sufficient even if the intensity of the light source is strong and the optical performance will not be sufficient either. Not limited in case where the exposure light is ultraviolet light previously explained, this situation may occur even if the exposure light is visible rays.

A method for depositing a metal fluoride thin film by using the spattering method may include a process for depositing a metal thin film on the substrate and a process for fluoridating the metal thin film by heating the metal thin film in a fluoride gas atmosphere (see Reference 1). It can form the thin film by using the spattering that uses a metal target in a fluorine-rich circumstance.
Reference 1; Japanese Patent Application Publication No. 2001-267233

However, in case where the fluoride thin film is formed on the optical element by using the method disclosed in Reference 1, plasma or charged particles may contact to the substrate of the optical element, and cause damage to the thin film being formed on the substrate or to the substrate of the optical element caused by charged particles. And binding defects may be generated. The damage caused by the contact of the charged particles is called “a plasma damage”. The binding defects increase the light absorption of the optical element.

Particularly, the wavelength of the light source is short in the exposure apparatus previously explained, a little light absorption of the thin film formed on the substrate of the optical element used in the exposure apparatus can cause a big influence. The exposure apparatus cannot perform sufficiently as a result.

The optical system in the exposure apparatus is generally formed by using a few dozens of lenses, and a plurality of dielectric materials which respectively have different refractions are formed on both sides of the lenses as an anti-reflection coating film of a multilayer having a few or a few dozens layers.

More, the optical element has a problem of generating heat on its surface if the anti-reflection film on the optical element has the light absorption. By generated heat, the surface of the optical element may deform, the bad influences such as aberrations may occur, or the projection and exposing performance of the circuit pattern may deteriorate. At the part where the exposure light concentrates, the heat may destroy the thin film.

### BRIEF SUMMARY OF THE INVENTION

Accordingly, it is an exemplary object to provide a deposition apparatus that can form a thin film on an object such as a substrate of an optical element without plasma damage, and can reduce the light absorption of the object.

To achieve above identified object, a deposition apparatus of one aspect according to the present invention generates plasma by applying voltage to a target, deposits target's particles that are vaporized by the plasma onto a surface of an object, and forms a thin film onto the surface of the object. Here, the deposition apparatus includes a plasma direction unit that directs the plasma generated by the application of the voltage.

The deposition apparatus may further includes a reactive gas supply unit which supplies the reactive gas that reacts to the target's particles. The reactive gas may be a fluoride gas. The reactive gas may be at least one selected from a fluorine gas, a tetrafluoromethane gas, a nitrogen trifluoride gas, or a trifluoromethane gas. The plasma direction unit may direct the plasma so that the plasma barely reaches to the object. The plasma direction unit may have a cylindrical shape. The plasma direction unit may use an electrically conductive material. The plasma direction unit may be provided on a target unit that is arranged so as to surround the target, wherein an inert gas is supplied into the target unit. The plasma direction unit may be provided on a target unit so as to face the object.

A magnet field whose direction is opposite to the direction of a magnetic field generated by the target's particles may be generated around the plasma direction unit. The target may be as least one selected from magnesium, lanthanum, gadolinium, aluminum, neodymium, sodium, and barium.

A deposition method of another aspect according to the present invention generates plasma by applying voltage to a target, deposits target's particles that are vaporized by the plasma onto a surface of an object, and forms a thin film onto the surface of the object. Here, the plasma is directed so as barely to reach to the object by the application of the voltage.

An optical element of still another aspect according to the present invention has a thin film. Here, the thin film is formed on a surface of the optical element by using the deposition method described above.

An optical system of still another aspect according to the present invention is formed by combining a plurality of optical elements. The optical elements use at least one optical element, on which a thin film is formed. Here, the thin film is formed on a surface of the optical element by using the deposition method described above.

Other objects and further features of the present invention will become readily apparent from the following description of the preferred embodiments with reference to accompanying drawings.

### BRIEF DESCRIPTION OF THE DRAWINGS

FIG. 1 is a schematic block diagram of a spattering apparatus of one embodiment according to the present invention.

FIG. 2 is a graph of the first example indicating the measurement result of electron density near a substrate of an optical element in the states of “with a chimney unit” and the measurement result of the same in the state of “without a chimney unit”.

FIG. 3 is a graph of the second example indicating the measurement result of light absorptions of the optical element having the thin film formed with the chimney unit and the measurement result of the same without the chimney unit.

FIG. 4 is a graph of the third example indicating the measurement result of electron density near the substrate of the optical element in the state of generating the magnetic field by a magnetic field generator and the measurement result of the same in the state of no magnetic fields.

FIG. 5 is a graph of the fourth example indicating the measurement result of electron density near the substrate of, the optical element in the state of generating the magnetic field by a magnetic field generator and the measurement result of the same in the state of no magnetic fields.

FIG. 6 is a graph of the fifth example indicating the measurement result of light absorption of the optical element having the thin film formed by using La metal target as an electrically conductive target with the chimney unit and the measurement result of the same without the chimney unit.

FIG. 7 is a schematic block diagram of a spattering apparatus used in the sixth example.

FIG. 8 is a graph indicating the thickness measurement result of the thin film formed on the optical element's substrate by using the spattering apparatus shown in FIG. 7.

FIG. 9 shows near the target of the spattering apparatus for explaining the chimney unit.

FIG. 10 shows near the target of the spattering apparatus for explaining the chimney unit with magnetic field.

### DETAILED DESCRIPTION OF THE PREFERRED EMBODIMENTS

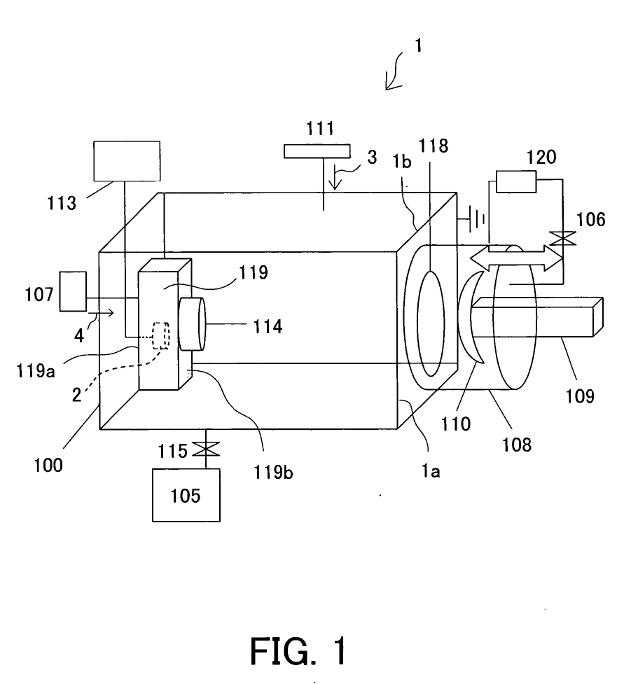

A description will now be given of a deposition apparatus of one embodiment according to the present invention. As shown in FIG. 1, a spattering apparatus 1 as the deposition apparatus includes a deposition chamber 100, a power supply 113, a supply unit 107 of an inert gas, a supply unit 111 of a reactive gas, and a sub chamber 108.

As shown in FIG. 1, the supply unit 111 of the reactive gas is connected with the deposition chamber 100 and a reactive gas 3 such as a fluoride gas can be supplied into the deposition chamber 100. The fluoride gas uses, for example, a fluorine gas (F₂), a tetrafluoromethane gas (CF₄), a nitrogen trifluoride gas (NF₄), a trifluoromethane gas (CHE₃), or a mixed gas of a few of them.

As explained later, the supply unit 107 of the inert gas is connected with a target unit 119 arranged in the deposition chamber 100, and an inert gas 4 such as an argon gas (Ar), a xenon gas (Xe), a neon gas (Ne), or a krypton gas (Kr) can be supplied into the target unit 119. The inert gas 4 may use a mixed gas of a few of them.

A vacuum unit 105 connected with the deposition chamber 100 via a bulb 115 can vacuum the deposition chamber 100. The vacuum unit 105 uses, for example, a dry pump, a turbo molecular pump, a refrigerator pump (cryopump), or a combination of them and can make the inside of the deposition chamber 100 be in the high vacuum state as 5.0 e⁻⁷ Torr (6.7 e⁻⁵ Pa).

An electrically conductive target 2 as a part of a thin film's material is arranger in the deposition chamber 100. The electrically conductive target 2 uses a metal material such as magnesium (Mg), lanthanum (La), gadolinium (Gd), aluminum (Al), neodymium (Nd), sodium (Na), or barium (Ba). The power supply 113 is connected with the electrically conductive target 2 and can apply the high voltage to the electrically conductive target 2. The power supply 113 uses a high-frequency superposed power supply for generating plasma, and can cope with the extraordinary discharge. The power supply 113 can supply direct rectangular periodical voltage and the frequency can be controlled in the range of 1 kHz to 350 kHz.

The target unit 119 is arranged so as to surround the electrically conductive target 2. The target unit 119 uses an electrically conductive material. The inert gas 4 is supplied into the target unit 119 by the supply unit 107 of the inert gas, and the inert gas 4 fills the atmosphere around the electrically conductive target 2.

One side 119a of the target unit 119, i.e., the side that the supply unit 107 of the inert gas is connected with is electrically earthed via the deposition chamber 100. As shown in FIG. 1, a chimney unit 114 as a plasma direction unit is provided on the other side 119b, i.e., the side that faces to the optical element's substrate 110. The chimney unit 114 is to direct the plasma generated by applying high voltage to the electrically conductive target 2. The chimney unit 2 uses an electrically conductive material such as a metal and has a cylindrical shape.

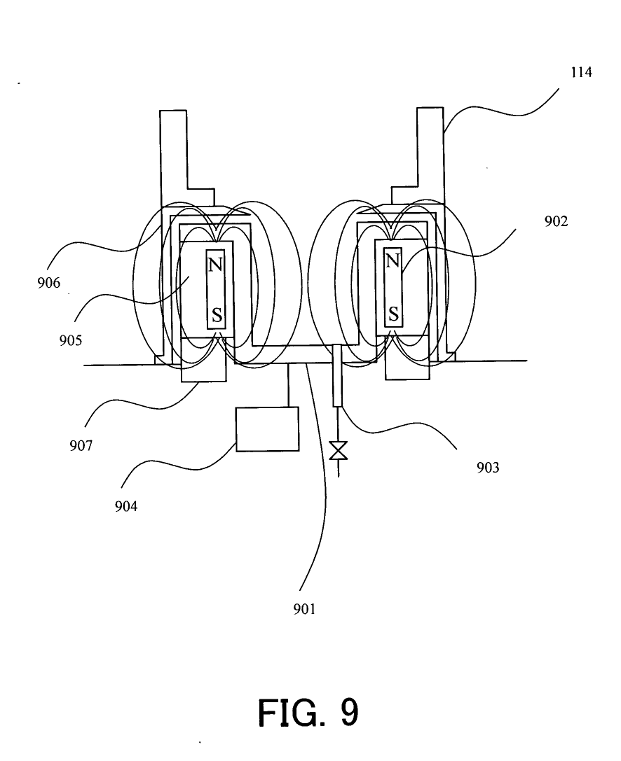

FIG. 9 shows the structure near the target and the detail of the chimney unit. FIG. 9 describes an electrically conductive target 901 that has a ring shape, a magnet 902, a supply unit 903 of the inert gas, a power supply 904, a target holder 905, a shield plate 906, and an insulator 906. The chimney unit 114 is fixed on the shield plate 906.

Back to FIG. 1 again, applying the high voltage to the electrically conductive target 2 by the power supply 113 generates the plasma, and the electrically conductive target 2 becomes particles (hereinafter, “the target particles”). By reacting the target particles with the reactive gas 3, an electrically conductive thin film as a reaction product of the target particles and the reactive gas 3 is formed on the surface of the optical element's substrate 110. if the reactive gas 3 uses a fluoride gas and the electrically conductive target uses a metal such as Mg, La, Gd, Nd, Na, or Ba, a thin film such as a magnesium fluoride film, a lanthanum fluoride film, a gadolinium fluoride film, an aluminum fluoride film, a neodymium fluoride film, a sodium fluoride film, or a barium fluoride film is formed on the surface of the optical element's substrate.

As the plasma generated in forming the film radiates to all directions, the plasma may reach to the surface of the optical element's substrate 110. If the plasma contacts with the surface of the optical element's substrate 110, the thin film in being formed or the optical element's substrate 110 may suffer the plasma damage and they cannot obtain the necessary optical performance. However, as the chimney unit 114 directs the plasma so as to reduce the amount of the plasma that reaches to the optical element's substrate 110, it can reduce the plasma damage mentioned above. Concretely, to avoid wide spreading of the plasma generated in the target unit 119, the chimney unit 119 having a cylindrical shape directs the plasma so as to narrow its radiation angle. The higher the sidewall of the cylindrical chimney unit 114 is (i.e., the longer the horizontal length of the chimney unit 114 shown in FIG. 1 is) or the smaller the diameter of the cylinder is, the better the direction efficiency of the plasma is. However, as these sizes may affect the film forming efficiency, the sizes of the chimney unit 114 should be determined in accordance with the balance of the direction efficiency of the plasma and the film forming efficiency.

The sub chamber 108 is provided on a side of the deposition chamber 100 opposite to the side that the target unit 119 is arranged via a gate bulb 118. A sub vacuum unit 120 and a bulb 106 can make the inside of the sub chamber 108 be vacuum state. The optical element's substrate 110 is arranged in the sub chamber 108 by a convey unit 109 in the state of conveyable. A plasma-measuring unit (not shown) that can measure parameters such as the electron density is arranged near the position of the optical element's substrate 110 in film forming.

A description will now given of a deposition method that forms the thin film on the surface of the optical element's substrate 110 by using the spattering apparatus 1.

At first, the electrically conductive target 2 is arranged in the target unit 119 that is arranged in the deposition chamber 100, and the deposition chamber 100 is next decompressed by the vacuum unit 105 with bulb 115 open until the pressure of the inside of the deposition chamber 100 will be in the high vacuum state as 5.0 e⁻⁷ Torr (6.7 e⁻⁵ Pa). With gate bulb 118 closed, the optical element's substrate 110 as an object is arranged in the sub chamber 108 by the convey unit 109 in the state of conveyable, and the inside of the sub chamber 108 will be in the high vacuum state like the same as the inside of the deposition chamber 100.

The reactive gas 3 is supplied into the deposition chamber 100 by the supply unit 111 of the reactive gas, the inert gas 4 is supplied into the target unit 119 by the supply unit 107 of the inert gas, and the pressure in the deposition chamber 100 is controlled to a specific pressure. After that, the power supply 113 applies the high voltage to the electrically conductive target 2 and the discharge occurs. Then, the plasma is generated. After settling the plasma impedance in stable, the gate bulb 118 is opened, and the optical element's substrate 110 is conveyed by the convey unit 109 to the position of specific distance from the electrically conductive target 2.

The target particles are produced from the electrically conductive target 2 by applying the high voltage and they react with the reactive gas 3. The depositing progresses by forming the reaction product as a thin film onto the surface of the optical element's substrate 110. The chimney unit 114 of the cylindrical shape is provided on the other side 119b of the target unit 119, and it directs the plasma by shielding the plasma by the sidewall of the cylinder. Therefore, the plasma barely reaches to the optical element's substrate 110, and the thin film and the optical element's substrate 110 hardly suffer the plasma damage.

The gases used in depositing or discharging needs to be processed. Therefore, the vacuum systems are connected to an absorption tower or a burning tower so as to prevent the emission of the gases to the air.

After a specific time passage from the beginning of deposition, the power supply 113 stops applying the voltage to stop deposition. The supplies of the reactive gas 3 by the supply unit 111 of the reactive gas 111 and the inert gas 4 by the supply unit 107 of the inert gas are stopped, and the optical element's substrate 110 is returned to the sub chamber 108 by the convey unit 109.

After that, the gate bulb 118 is closed, a nitrogen gas is supplied into the sub chamber 108 by a nitrogen gas supply unit (not shown) till approximately atmospheric pressure, and the optical element's substrate 110 is picked up. The picked up optical element's substrate 110 after deposition is measured on its absorption index at vacuum ultraviolet light by a vacuum ultraviolet light spectrometer (not shown) and is estimated on its optical performance.

### THE FIRST EXAMPLE

The electrically conductive target 2 uses a Mg metal target. The Mg metal target is removably arranged in the target unit 119. The plasma-measuring unit measures the electron density near the optical element's substrate 110 with using the chimney unit 114 and the electron density near the same without using the chimney unit 114.

The power supply 113 uses the DC power supply. Sprt-leV (manufactured by AE corp.) is arranged between the Mg target and the DC power supply for coping with the extraordinary discharge. 200 sccm of the Ar gas as the inert gas 4 and 200 sccm of the F₂ gas diluted to 12% by the Ar gas as the reactive gas 3 are supplied into the deposition chamber 100. Supplying the power of 500W from the DC power supply to the Mg metal target generates the discharge. The pressure in depositing is 4 mTorr (0.53 Pa). The plasma-measuring unit measures the electron density near the optical element's substrate 110 after the target voltage is settled in stable.

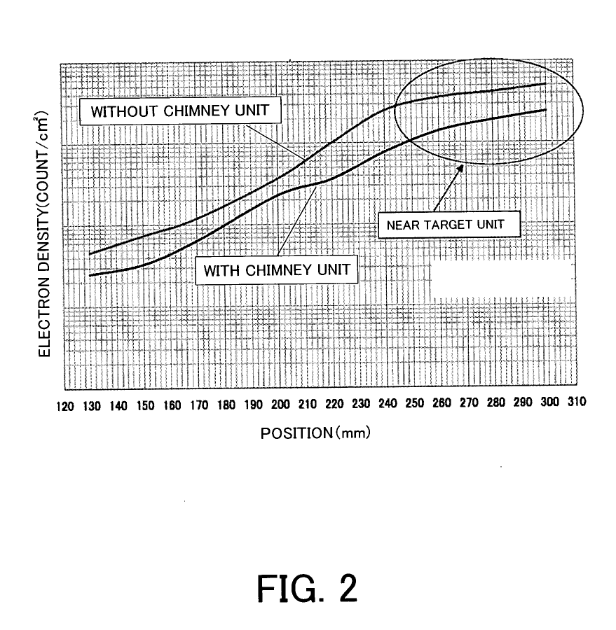

The measuring results are shown in FIG. 2. In FIG. 2, lateral axis indicates the distance along the side 1b from approximately the center of the side 1a of the deposition chamber 100. The position of approximately the center of the side 1b corresponds to 300 mm. As shown in FIG. 2, the electron densities become bigger in accordance with closing to the center of the side 1b. The electron density measured with chimney unit 114 is smaller than that without chimney unit 114. That is, it indicates that the chimney unit 114 directs the plasma so that the plasma barely reaches to the optical element's substrate 110.

### THE SECOND EXAMPLE

In the same condition as the first example previously described, the optical element's substrate 110 uses a calcium fluoride (CaF₂) composite crystal substrate of 2 mm thick. The CaF₂ composite crystal substrate is arranged on the convey unit 109 and a MgF₂ thin film is deposited on the CaF₂ composite crystal substrate by spattering apparatus 1 after being removed the residue (the dirt or the dust) adhered on the surface by the solvent that is made from alcohol and ether of 1:3 and the residual organic pollution by UV/O3 unit. The depositions are performed in both cases with the chimney unit 114 and without the chimney unit 114.

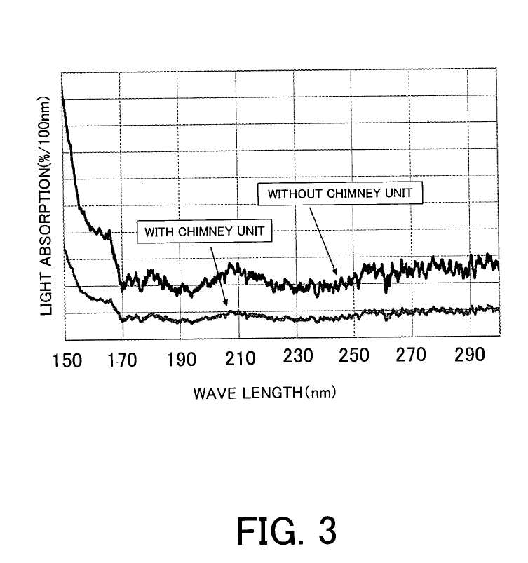

FIG. 3 show the results of the light absorption by the CaF₂ composite crystal substrate after deposition measured by the vacuum ultraviolet spectrometer. In FIG. 3, the light absorption on condition without chimney unit at the wavelength of 170 nm per unit film thickness corresponds to “1”. As shown in FIG. 3, the light absorption with the chimney unit 114 is smaller than that without the chimney unit 114 in all measured wavelengths. Therefore, the thin film having good light absorption performance can be formed on the optical element's substrate with using chimney unit 114.

As described in the first and second examples above, charged particles harm the damages to the thin film and the optical element's substrate near the border of them and the light absorption increases from the long wave area to the short wave area by the damages. By using the chimney unit 114, the electron density is reduced near the optical element's substrate. As the results, the plasma damage can be reduced and the light absorption of the optical element can be small.

### THE THIRD EXAMPLE

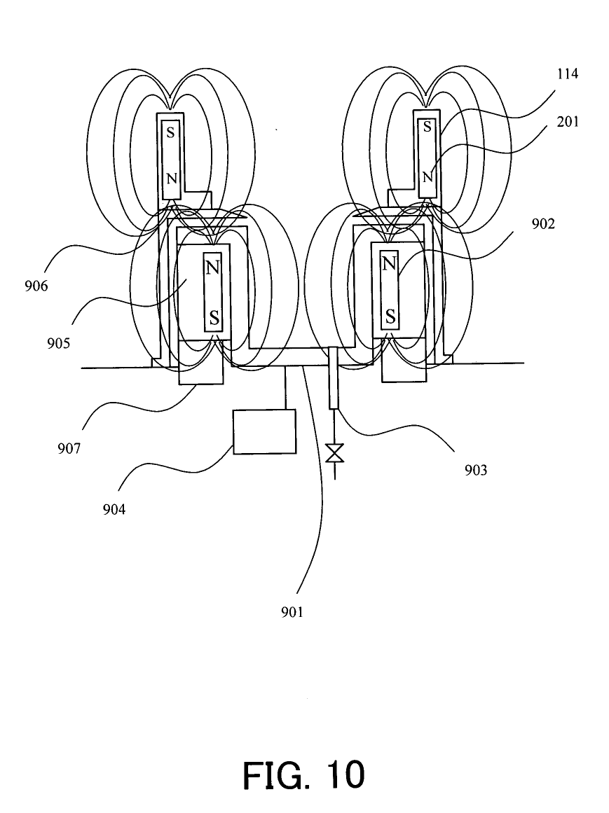

FIG. 10 shows that a magnetic field generator is provided on or in the sidewall of the cylindrical chimney unit 114 arranged in the deposition chamber 100 of the spattering apparatus 1. In FIG. 10, the same elements shown in FIG. 9 are numbered the same and the explanations of them are omitted. In FIG. 10, the magnetic field generator 201 is provided in the sidewall of the cylindrical chimney unit 114. The magnetic field generator may use a permanent magnet or an electromagnet and is arranged to form the magnetic field whose direction is opposite to the direction of a magnetic field generated by the target particles which is produced by applying the voltage to the electrically conductive target 2. Thus, the magnetic field whose direction is opposite to the direction of the magnetic field generated by the target particles is generated around the chimney unit 114.

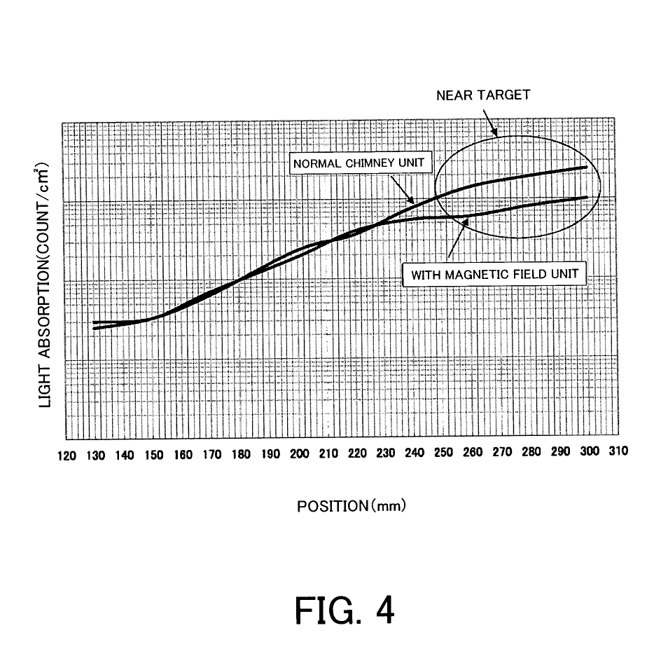

The depositions are performed in conditions where the magnetic field generator generates the magnetic field whose direction is opposite to the direction of the magnetic field generated by the target particles and where the magnetic field generator does not generate the magnetic field. The electrically conductive target 2, the reactive gas 3, and the inert gas 4 use the same as used in the first example described above. The results of the electron density measured by the plasma-measuring unit in deposition are shown in FIG. 4. The lateral axis and the vertical axis are the same as in FIG. 2.

As indicated in FIG. 4, the electron density near the optical element's substrate 110 (i.e., the position of 230 mm-300 mm) is smaller when the magnetic field generator generates the magnetic field whose direction is opposite to the direction of the magnetic field generated by the target particles than the same when the magnetic field generator does not generate the magnetic field. Thus, the magnetic field generator can further improve directing of the plasma and can further reduce the plasma that can reach to the optical element's substrate 110. Therefore, the plasma damage to the optical element's substrate 110 and the film formed on its surface can be smaller.

### THE FOURTH EXAMPLE

In the same condition as the third example previously described, the optical element's substrate 110 uses a calcium fluoride (CaF₂) composite crystal substrate of 2 mm thick. The residue and the residual organic pollution are removed from the surface of the CaF₂ composite crystal substrate in the same way as the third example. The depositions are performed in conditions where the magnetic field generator generates the magnetic field whose direction is opposite to the direction of the magnetic field generated by the target particles and where the magnetic field generator does not generate the magnetic field.

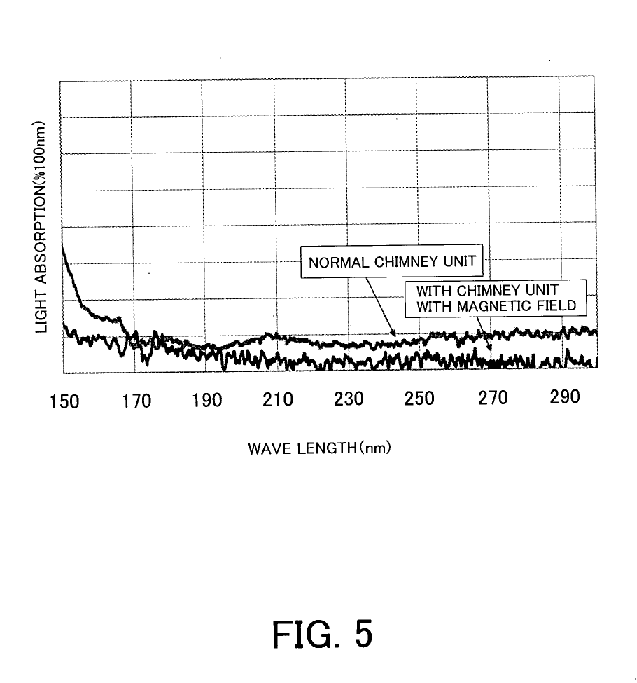

FIG. 5 show the results of the light absorption by the CaF₂ composite crystal substrate after deposition measured by the vacuum ultraviolet spectrometer. In FIG. 5, the light absorption on condition without chimney unit at the wavelength of 170 nm per unit film thickness corresponds to “1”. As shown in FIG. 5, the light absorption with the chimney unit 114 is smaller than that without the chimney unit 114 in all measured wavelengths. Particularly, the light absorption is remarkably reduced in the long wave area, and is also reduced in, for example, the wavelength areas of ArF laser (193 nm) and F₂ laser (157 nm). Therefore, the thin film having good light absorption performance can be formed on the optical element's substrate with generating the magnetic field by the magnetic field generator.

### THE FIFTH EXAMPLE

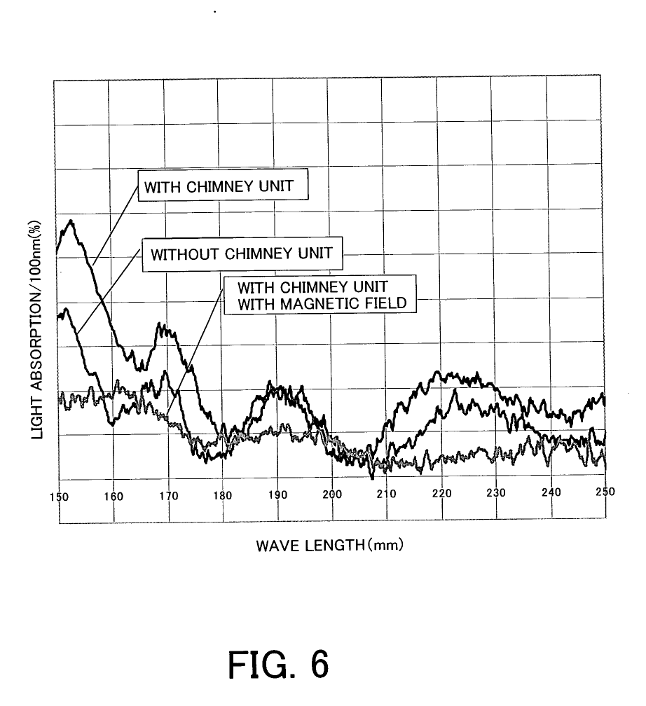

The electrically conductive target 2 uses a La metal target, and 150 sccm of the Ar gas as the inert gas 4 and 150 sccm of the F₂ gas diluted to 12% by the Ar gas as the reactive gas 3 are supplied into the deposition chamber 100. The pressure in deposition is 3 mTorr (0.40 Pa). The power supply 113 uses the DC power supply and applies the power of 400W to the La metal target. FIG. 6 shows the measurement results on conditions with chimney unit 114 and without chimney unit 114.

As shown in FIG. 6, the trend of the light absorption performance of the deposited optical element is not changed even if the electrically conductive thin film has been changed from magnesium fluoride to lanthanum fluoride in accordance with the change of the material of the electrically conductive target 2 from Mg to La. Thus, if the material of the electrically conductive target 2 has been changed, the chimney unit 114 directs the plasma so that the plasma barely reaches near the optical element's substrate 110.

### THE SIXTH EXAMPLE

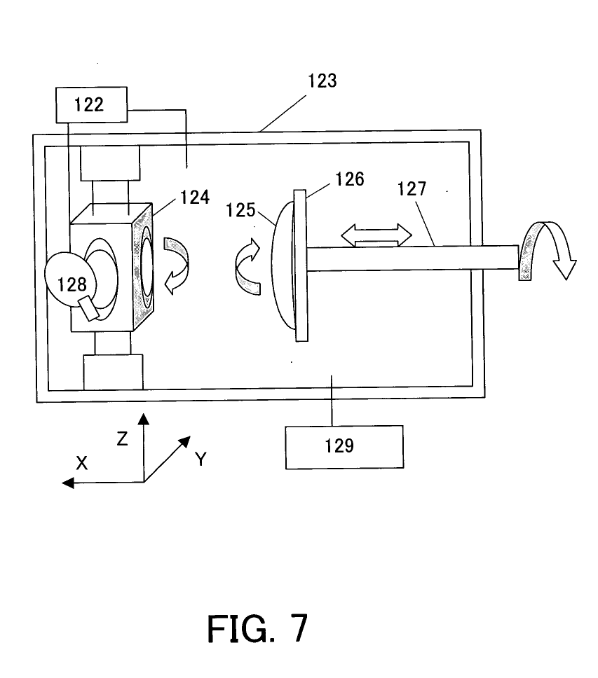

In the sixth example, a spattering apparatus 10 shown in FIG. 7 performs the deposition. The spattering apparatus 10 is approximately the same as the spattering apparatus 1 shown in FIG. 1. However, the spattering apparatus 10 can further deposit with changing the relative position of the optical element's substrate 125 and the electrically conductive target. For evening the thickness of the thin film formed on the optical element's substrate 125, the spattering apparatus 10 of the sixth example can, for example, deposit with rotating the optical element's substrate 125 around the rotation axis 127.

Supporting the optical element's substrate 125 on a supporting member 126 and attaching them on a convey unit (not shown) in advance, the optical element's substrate 125 is positioned in a sub chamber (not shown). A vacuum unit 129 decompresses a deposition chamber 123 and the sub chamber till high vacuum state and the convey unit conveys the optical element's substrate 125 into the deposition chamber 123. A gas supply unit 122 supplies the inert gas and the reactive gas into the deposition chamber 123 and the deposition is begun by applying the voltage to the electrically conductive target 124 arranged in a target unit 124.

The target unit 124 has a shutter 128 as shown in FIG. 7. The shutter will be closed until the plasma impedance becomes stable so that the deposition cannot be begun. The shutter is opened after the plasma impedance has been stable and the deposition is performed with rotating the optical element's substrate 125 around the X-axis with centering the rotation axis 127. Simultaneously, the optical element's substrate 125 and the target unit 124 are moved in the Y direction along the rotation axis 127 so that the thin film formed on the surface of the optical element's substrate 125 will be even.

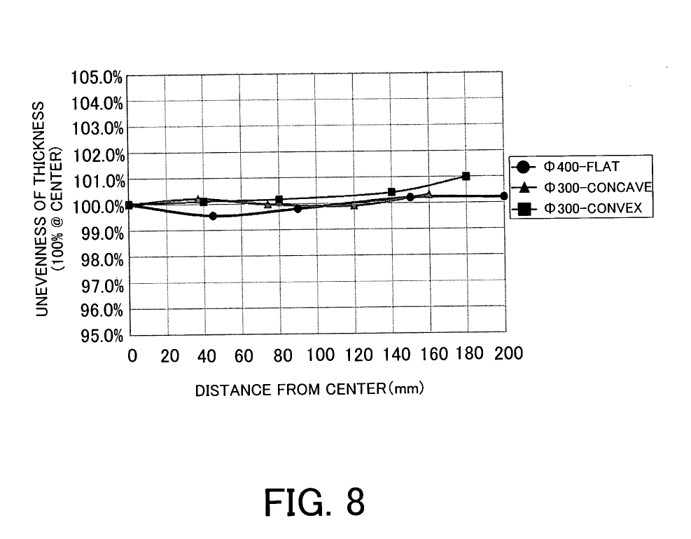

The measured result of the unevenness of the thin film that is formed on the surface of the optical element's substrate 125 is shown in FIG. 8. In FIG. 8, the vertical axis indicates the relative thickness of the thin film assuming the thickness at the center of the optical element's substrate 125 is 100. The lateral axis indicates the distance from the center of the optical element's substrate 125 to the measuring position. The optical element's substrate uses a flat substrate having a diameter of 400 mm, a concave substrate having a diameter of 300 mm, or a convex substrate having a diameter of 300 mm.

As shown in FIG. 8, the unevenness of the film thickness is 1% or smaller in all optical element's substrates. Therefore, the thin film that has a thickness sufficiently even can be formed on large diameter lenses or large diameter mirrors used in an optical system of an exposure apparatus such as “the stepper” by using this deposition method.

Further, the present invention is not limited to these preferred embodiments, and various variations and modifications may be made without departing from the scope of the present invention.

According to the present invention, a thin film that has a good performance can be formed on an object such as an optical element with hardly suffering the plasma damage, and the light absorption of the object can be reduced. Even thickness this film can be formed on the object that has a large area and the object can be the optical element that is suitable for the exposure apparatus.

This application claims priority benefit under 35 U.S.C. § 119 based on Japanese Patent Application No. 2003-344387 filed on Oct. 2, 2003, which is hereby incorporated by reference herein in its entirety as if fully set forth herein.

1. A deposition apparatus that generates plasma by applying voltage to a target, deposits target's particles that are vaporized by the plasma onto a surface of an object, and forms a thin film onto the surface of the object,
said deposition apparatus comprising a plasma direction unit that directs the plasma generated by the application of the voltage.

2. The deposition apparatus according to claim 1 further comprising a reactive gas supply unit which supplies the reactive gas that reacts to the target's particles.

3. The deposition apparatus according to claim 2, wherein the reactive gas is a fluoride gas.

4. The deposition apparatus according to claim 3, wherein the reactive gas is at least one selected from a fluorine gas, a tetrafluoromethane gas, a nitrogen trifluoride gas, and a trifluoromethane gas.

5. The deposition apparatus according to claim 1, wherein the plasma direction unit directs the plasma so that the plasma barely reaches to the object.

6. The deposition apparatus according to claim 1, wherein the plasma direction unit has a cylindrical shape.

7. The deposition apparatus according to claim 1, wherein the plasma direction unit uses an electrically conductive material.

8. The deposition apparatus according to claim 1, wherein the plasma direction unit is provided on a target unit that is arranged so as to surround the target, wherein an inert gas is supplied into the target unit.

9. The deposition apparatus according to claim 1, the plasma direction unit is provided on a target unit so as to face the object.

10. The deposition apparatus according to claim 1, wherein a magnet field whose direction is opposite to the direction of a magnetic field generated by the target's particles is generated around the plasma direction unit.

11. The deposition apparatus according to claim 1, wherein the target is as least one selected from magnesium, lanthanum, gadolinium, aluminum, neodymium, sodium, and barium.

12. A deposition method that generates plasma by applying voltage to a target, deposits target's particles that are vaporized by the plasma onto a surface of an object, and forms a thin film onto the surface of the object,
wherein the plasma is directed so as barely to reach to the object by the application of the voltage.

13. An optical element on which a thin film is formed, wherein the thin film is formed on a surface of the optical element by using a deposition method that generates plasma by applying voltage to a target, deposits target's particles that are vaporized by the plasma onto the surface of the optical element, and forms a thin film onto the surface of the optical element,
wherein the plasma is directed so as barely to reach to the optical element by the application of the voltage.

14. An optical system that is formed by combining a plurality of optical elements, said optical elements use at least one optical element on which a thin film is formed,
wherein the thin film is formed on a surface of the optical element by using a deposition method that generates plasma by applying voltage to a target, deposits target's particles that are vaporized by the plasma onto the surface of the optical element, and forms a thin film onto the surface of the optical element,
wherein the plasma is directed so as barely to reach to the optical element by the application of the voltage.
